(19) United States
(12) Patent Application Publication
(10) Pub. No.: US 2024/0404797 A1
(43) Pub. Date: Dec. 5, 2024

(54) Workpiece Processing Apparatus and Methods for the Treatment of Workpieces

(71) Applicants: Beijing E-Town Semiconductor Technology Co., Ltd., Beijing (CN); Mattson Technology, Inc., Fremont, CA (US)

(72) Inventors: Ting Xie, Fremont, CA (US); Jiaying Yang, Fremont, CA (US); Haichun Yang, San Jose, CA (US)

(21) Appl. No.: 18/677,456

(22) Filed: May 29, 2024

Related U.S. Application Data
(60) Provisional application No. 63/504,903, filed on May 30, 2023.

(51) Int. Cl. H01J 37/32

(52) U.S. Cl. CPC H01J 37/32724; H01J 37/3211; H01J 37/32522; H01J 37/32642; H01J 2237/002; H01J 2237/20235

(57) ABSTRACT

Systems and methods for thermal treatment of a workpiece are provided. In one example, a method for conducting a treatment process on a workpiece, such as a thermal treatment process, an annealing treatment process, an oxidizing treatment process, or a reducing treatment process in a processing apparatus is provided. The processing apparatus includes a plasma chamber and a processing chamber. The plasma chamber and the processing chamber are separated by a plurality of separation grids or grid plates. The separation grids or grid plates operable to filter ions generated in the plasma chamber. The processing chamber has a workpiece support operable to support a workpiece.

### PRIORITY CLAIM

The present application claims the filing benefit of U.S. Provisional Application Ser. No. 63/504,903 having a filing date of May 30, 2023, which is incorporated herein by reference in its entirety.

### FIELD

The present disclosure relates generally to apparatus, systems, and methods for processing a workpiece using a plasma source.

### BACKGROUND

Plasma processing is widely used in the semiconductor industry for deposition, etching, resist removal, and related processing of semiconductor wafers and other substrates. Plasma sources (e.g., microwave, ECR, inductive coupling, etc.) are often used for plasma processing to produce high density plasma and reactive species for processing workpieces. Plasma processing tools can include a plasma chamber where plasma is generated and a separate processing chamber where the substrate is processed. The processing chamber can be “downstream” of the plasma chamber such that there is no direct exposure of the substrate to the plasma. A separation grid can be used to separate the processing chamber from the plasma chamber. The separation grid can be transparent to neutral particles but not transparent to charged particles from the plasma. The separation grid can include one or more sheets or plates of material with holes.

### SUMMARY

Aspects and advantages of embodiments of the present disclosure will be set forth in part in the following description, or may be learned from the description, or may be learned through practice of the embodiments.

Example aspects of the present disclosure are directed to a processing apparatus for processing a workpiece including a processing chamber; a plasma chamber separated from the processing chamber; a gas delivery system configured to deliver one or more process gases to the plasma chamber; a plasma source configured to generate a plurality of radicals in a plasma from the one or more process gases in the plasma chamber; a workpiece support disposed within the processing chamber, the workpiece support configured to support a workpiece; and a focus ring configured to direct the plurality of radicals towards the workpiece.

Example aspects of the present disclosure are also directed to a method for conducting a thermal treatment process on a workpiece in a processing apparatus, the processing apparatus comprising a plasma chamber and a processing chamber, and the processing chamber having a workpiece support operable to support a workpiece. The method includes placing the workpiece on the workpiece support in the processing chamber; moving the workpiece support towards the plasma chamber to close a distance between a focus ring and the workpiece support; and conducting a radical treatment process on the workpiece, comprising exposing the workpiece to hydrogen radicals in the processing chamber, the hydrogen radicals configured to close one or more seams in a metal layer.

These and other features, aspects, and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts an example plasma processing apparatus having the workpiece in a first position according to example embodiments of the present disclosure;

FIG. 1 depicts an example plasma processing apparatus having the workpiece in a second position according to example embodiments of the present disclosure;

FIG. 3 depicts an example post plasma gas injection according to example embodiments of the present disclosure;

FIG. 4 depicts an example radical treatment process on a high aspect ratio structure according to example embodiments of the present disclosure;

FIG. 5 depicts an example radical treatment process on a high aspect ratio structure according to example embodiments of the present disclosure;

FIG. 6 depicts an example radical treatment process on a high aspect ratio structure according to example embodiments of the present disclosure;

FIG. 7 depicts an example radical treatment process on a high aspect ratio structure according to example embodiments of the present disclosure; and

FIG. 8 depicts a flow diagram of an example method according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Example aspects of the present disclosure are directed to a processing apparatus for processing a workpiece including a processing chamber; a plasma chamber separated from the processing chamber; a gas delivery system configured to deliver one or more process gases to the plasma chamber; a plasma source configured to generate a plurality of radicals in a plasma from the one or more process gases in the plasma chamber; a workpiece support disposed within the processing chamber, the workpiece support configured to support a workpiece; and a focus ring configured to direct the plurality of radicals towards the workpiece.

For example, it can be difficult to produce and maintain hydrogen radicals in processing equipment. For instance, reactive hydrogen radicals often recombine with other hydrogen radicals along the walls and surface of the processing equipment, such as along the wall of the plasma or processing chamber or along the surface of the separation grid. Reduction of the recombination of hydrogen radicals can lead to an increase of available hydrogen radicals for processing. Reducing the temperature of the surface can reduce hydrogen radical recombination. As such, the plasma chamber, processing chamber, and separation grid of the present apparatus are equipped with various cooling mechanisms to prevent hydrogen radical recombination.

Further, additional magnetic coils can be disposed on or around the plasma chamber that can provide an auxiliary magnetic field. This auxiliary magnetic field can provide extra energy for plasma generation and can help to confine the plasma towards the center of the plasma chamber such that recombination of hydrogen radicals along the surface of the chamber wall is reduced.

Additionally, the processing apparatus is equipped with a focus ring disposed underneath the separation grid assembly. As hydrogen radicals move through the separation grid assembly they enter the processing chamber and can be exposed to a workpiece. However, diffusion of hydrogen radicals throughout the processing chamber can occur resulting in fewer hydrogen radicals at the surface of the workpiece. Accordingly, the focus ring serves to prevent diffusion of hydrogen radicals in the processing chamber thus guiding more of the hydrogen radicals to the surface of the workpiece.

Example aspects of the present disclosure can provide a number of technical effects and benefits. For instance, the apparatus provided herein can be utilized to generate and maintain radicals (e.g., hydrogen radicals) while preventing recombination of radicals along surfaces of the apparatus. Further, the apparatus can more effectively guide radicals in the processing chamber ensuring that higher amounts of radicals actually reach the workpiece surface. Accordingly, the present apparatus can generate and maintain radicals and deliver them to the workpiece in a more efficient manner thereby reducing processing costs and processing time. The methods provided herein also provide for a higher surface concentration of hydrogen radicals for diffusion into the metal layer or workpiece structure as compared to other thermal treatments. Furthermore, the methods provided herein may be operated at lower temperatures thus reducing the overall energy usage and thermal budget for the process. The methods provided herein may also require a lower total chemical usage as compared to other thermal processes.

Aspects of the present disclosure are discussed with reference to a “workpiece,” “substrate,” or “wafer” (e.g., semiconductor wafer) for purposes of illustration and discussion. Those of ordinary skill in the art, using the disclosures provided herein, will understand that the example aspects of the present disclosure can be used in association with any semiconductor substrate or other suitable substrate. In addition, the use of the term “about” in conjunction with a numerical value is intended to refer to within twenty percent (20%) of the stated numerical value. A “workpiece support” refers to any structure that can be used to support a workpiece.

As used herein, a “remote plasma” refers to a plasma generated remotely from a workpiece, such as in a plasma chamber separated from a workpiece by a separation grid. As used herein, a “direct plasma” refers to a plasma that is directly exposed to a workpiece, such as a plasma generated in a processing chamber having a workpiece support operable to support the workpiece.

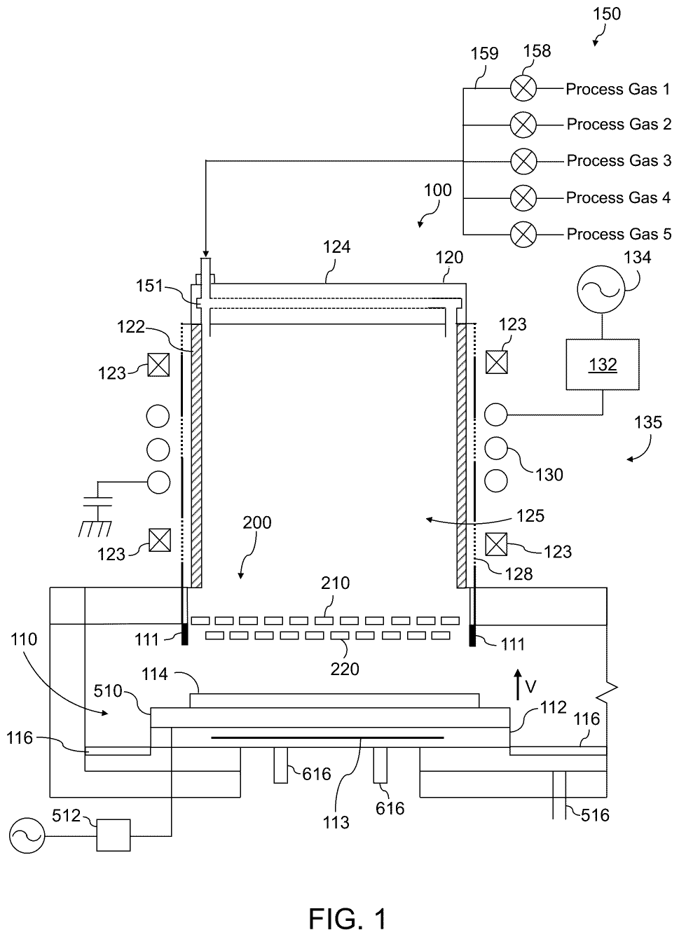

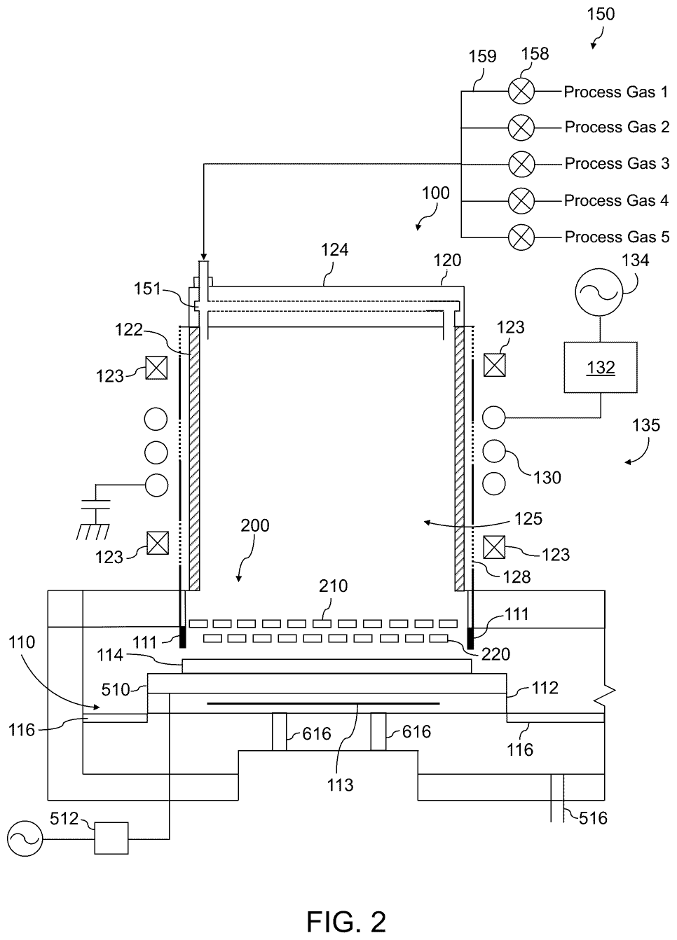

FIG. 1 depicts an example plasma processing apparatus 100 that can be used to perform processes according to example embodiments of the present disclosure. As illustrated, plasma processing apparatus 100 includes a processing chamber 110 and a plasma chamber 120 that is separated from the processing chamber 110. Processing chamber 110 includes a workpiece support or workpiece support 112 operable to hold a workpiece 114 to be processed, such as a semiconductor wafer. In this example illustration, a plasma is generated in plasma chamber 120 (i.e., plasma generation region) by an inductively coupled plasma source 135 and desired species are channeled from the plasma chamber 120 to the surface of workpiece 114 through a separation grid assembly 200.

Aspects of the present disclosure are discussed with reference to an inductively coupled plasma source for purposes of illustration and discussion. Those of ordinary skill in the art, using the disclosures provided herein, will understand that any plasma source (e.g., inductively coupled plasma source, capacitively coupled plasma source, etc.) can be used without deviating from the scope of the present disclosure.

The plasma chamber 120 includes a dielectric side wall 122 and a ceiling 124. The dielectric side wall 122, ceiling 124, and separation grid 200 define a plasma chamber interior 125. Dielectric side wall 122 can be formed from a dielectric material, such as quartz and/or alumina. Dielectric side wall 122 can be formed from a ceramic material. The inductively coupled plasma source 135 can include an induction coil 130 disposed adjacent the dielectric side wall 122 about the plasma chamber 120. The induction coil 130 is coupled to an RF power generator 134 through a suitable matching network 132. Process gases, for example a fluorine-containing gas or a hydrogen-containing gas, can be provided to the chamber interior from gas supply 150 and annular gas distribution channel 151 or other suitable gas introduction mechanism. When the induction coil 130 is energized with RF power from the RF power generator 134, plasma can be generated in the plasma chamber 120. In a particular embodiment, the plasma processing apparatus 100 can include an optional grounded Faraday shield 128 to reduce capacitive coupling of the induction coil 130 to the plasma.

One or more magnetic coils 123 can be disposed around the plasma chamber 120. For instance, as shown, the one or more magnetic coils 123 can be disposed above and below the induction coil 130. The one or more magnetic coils 123 are disposed adjacent to the dielectric side wall 122 of the plasma chamber 120. While not depicted, the magnetic coils 123 can also be placed along the ceiling 124 of the plasma chamber 120. The magnetic coils 123 can be used to increase hydrogen radical density in the plasma chamber 120. For instance, the magnetic coils 123 can be operated to increase hydrogen radical density in the plasma. In other embodiments, the magnetic coils 123 can be operated during generation of the plasma to facilitate dissociation of hydrogen to produce hydrogen radicals. The magnetic coils 123 can also serve to prevent and reduce recombination of hydrogen at or along the dielectric side wall 122 of the plasma chamber 120. The magnetic coils 123 can be formed from any material capable of generating a magnetic field. For instance, the magnetic coils 123 can be formed from a metal material (e.g., copper) through which an electrical current can be passed to produce a magnetic wave. In other embodiments, can be formed from a permanent magnet capable of generating a providing a steady magnetic field. Notably, the Faraday shield 128 is disposed between the magnetic coils 123 and the dielectric side wall 122.

A cooling mechanism 126 can be used to cool the dielectric side wall 122 of the plasma chamber 120. For instance, in certain embodiments, the cooling mechanism 126 can include one or more cooling channels disposed on or within the dielectric side wall 122. A cooling fluid such as cooled water or air can be provided through the cooling channels in order to reduce the temperature of the dielectric side wall 122. Other known cooling mechanisms can also be utilized, including fans and/or heat sinks. In embodiments, the cooling mechanism 126 can be configured to reduce the temperature of the dielectric side wall 122 during plasma generation. For instance, the cooling mechanism 126 can reduce the temperature of the dielectric side wall 122 by at least 10° C. and up to about 70° C. Reducing the temperature of the dielectric side wall 122 during processing can prevent hydrogen recombination along the interior of the plasma chamber 120 at the dielectric side wall 122, thus promoting the longevity of atomic hydrogen present in the plasma.

As shown in FIG. 1, a separation grid 200 separates the plasma chamber 120 from the processing chamber 110. The separation grid 200 can be used to perform ion filtering from a mixture generated by plasma in the plasma chamber 120 to generate a filtered mixture. The filtered mixture can be exposed to the workpiece 114 in the processing chamber 110.

In some embodiments, the separation grid 200 can be a multi-plate separation grid. For instance, the separation grid 200 can include a first grid plate 210 and a second grid plate 220 that are spaced apart in parallel relationship to one another. The first grid plate 210 and the second grid plate 220 can be separated by a distance.

The first grid plate 210 can have a first grid pattern having a plurality of holes. The second grid plate 220 can have a second grid pattern having a plurality of holes. The first grid pattern can be the same as or different from the second grid pattern. Charged particles can recombine on the walls in their path through the holes of each grid plate 210, 220 in the separation grid. Neutral species (e.g., radicals) can flow relatively freely through the holes in the first grid plate 210 and the second grid plate 220. The size of the holes and thickness of each grid plate 210 and 220 can affect transparency for both charged and neutral particles.

In some embodiments, the first grid plate 210 can be made of metal (e.g., aluminum) or other electrically conductive material and/or the second grid plate 220 can be made from either an electrically conductive material or dielectric material (e.g., quartz, ceramic, etc.). In some embodiments, the first grid plate 210 and/or the second grid plate 220 can be made of other materials, such as silicon or silicon carbide. In the event a grid plate is made of metal or other electrically conductive material, the grid plate can be grounded. In some embodiments, the grid assembly can include a single grid with one grid plate.

In some embodiments, the separation grid 200 can be configured to filter ions with an efficiency greater than or equal to about 90%, such as greater than or equal to about 95%. A percentage efficiency for ion filtering refers to the amount of ions removed from the mixture relative to the total number of ions in the mixture. For instance, an efficiency of about 90% indicates that about 90% of the ions are removed during filtering. An efficiency of about 95% indicates that about 95% of the ions are removed during filtering.

In some embodiments, the separation grid can be a multi-plate separation grid. The multi-plate separation grid can have multiple separation grid plates in parallel. The arrangement and alignment of holes in the grid plate can be selected to provide a desired efficiency for ion filtering, such as greater than or equal to about 95%.

In embodiments, the grid plates 210, 220 can include a cooling channel configured to reduce the temperature of the separation grid assembly 200 during processing. For instance, each grid plate 210, 220 can include one or more cooling channels disposed therein. Fluid (e.g., water or air) can be provided to the cooling channels in order to remove and carry heat away from the separation grid assembly 200 thereby reducing the overall temperature of the separation grid assembly. In such embodiment, cooling of the separation grid assembly 200 reduces the recombination of hydrogen at or along a surface of the grid plates 210, 220, thereby preserving hydrogen radicals generated in the plasma.

As shown in FIG. 1, according to example aspects of the present disclosure, the apparatus 100 can include a gas delivery system 150 configured to deliver process gas to the plasma chamber 120, for instance, via gas distribution channel 151 or other distribution system (e.g., showerhead). The gas delivery system 150 can include a plurality of feed gas lines 159. The feed gas lines 159 can be controlled using valves 158 and/or mass flow controllers to deliver a desired amount of gases into the plasma chamber 120 as process gas. As shown in FIG. 1, the gas delivery system 150 can include feed gas line(s) for delivery of different process gases (e.g., process gas 1, process gas 2, etc.). In embodiments, one feed gas line can be configured to provide an oxygen-containing gas (e.g. O₂, O₃, N₂O, H₂O) and another feed gas line can be configured for delivery of a hydrogen-containing gas (e.g., H₂, CH₄, NH₃, D₂). Still another feed gas line can be configured for delivering a hydrocarbon-containing gas (e.g., CH₄). Other feed gas lines containing other gases can be added as needed. In some embodiments, the process gas can be mixed with an inert gas that can be called a “carrier” gas, such as He, Ar, Ne, Xe, or N₂. A control valve 158 can be used to control a flow rate of each feed gas line to flow a process gas into the plasma chamber 120. The plasma processing apparatus 100 of FIG. 1 can implement a hydrogen radical treatment process utilizing a remote plasma.

The workpiece support 112 can be movable in a vertical direction V. For instance, the workpiece support 112 can include a vertical lift 616 that can be configured to adjust a distance between the workpiece support 112 and the separation grid assembly 200 and/or focus ring 111. As one example, the workpiece support 112 can be located in a first vertical position for placing the workpiece on or off of the workpiece support 112 for processing. The workpiece support 112 can then be moved to a second vertical position for processing the workpiece that is closer to the separation grid assembly 200 and the focus ring 111 (shown in FIG. 2). For instance, the workpiece support 112 is configured to adjust a distance between the workpiece support and focus ring 111. For instance, as shown in FIG. 2, the workpiece support 112 is in a second vertical position where the workpiece 114 is closer to both the separation grid assembly 200 and the focus ring 111. In such embodiments, the distance between an end of the focus ring 111 and the workpiece support 112 is from about 1 mm to about 50 mm, such as from about 5 mm to about 45 mm, such as from about 10 mm to about 40 mm, such as from about 15 mm to about 35 mm, such as from about 20 mm to about 30 mm. In such embodiments, the focus ring 111 and the distance between the workpiece 114 and the separation grid assembly 200 can improve radical flow and exposure on the workpiece 114. For instance, the focus ring 111 prevents radicals from flowing laterally into the processing chamber 110 thus preventing them from contacting the surface of the workpiece 114. Accordingly, the focus ring 111 prevents radicals from the plasma from diffusing to different areas of the processing chamber 110. The focus ring 111 can be formed from any suitable material including quartz, alumina, ceramic, and combinations thereof.

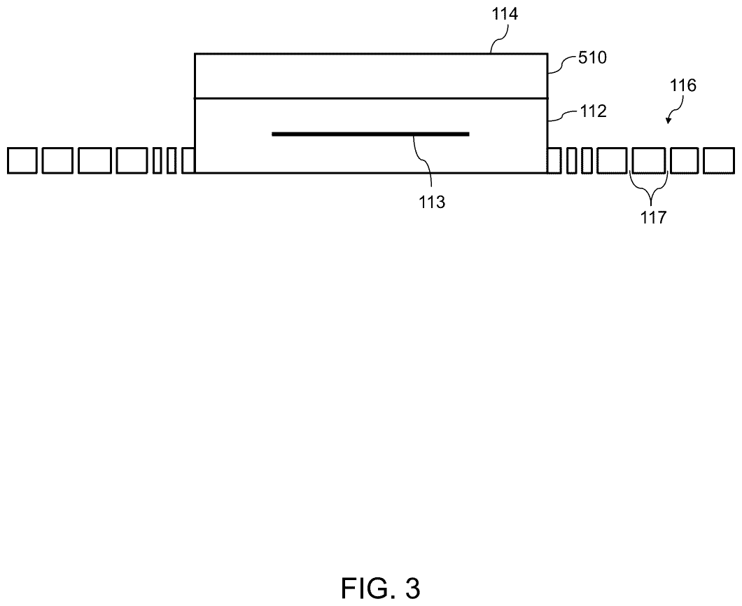

A pumping plate 116 is disposed in the processing chamber 110. Generally, the pumping plate 116 can be disposed around or on each side of the workpiece support 112. The pumping plate 116 can span the distance from the side of the workpiece support 112 to the inner wall of the processing chamber 110. As shown in FIG. 3, the pumping plate 116 can include one or more apertures or channels through which radicals or process gas can pass to be exhausted from the processing chamber 110. The pumping plate 116 can include a greater amount or number of apertures 117 or channels disposed closest to the workpiece support 112. For instance, as shown, there is a higher concentration of apertures 117 or channels disposed on the portion of the pumping plate 116 closer to the workpiece support 112 and fewer apertures 117 or channels disposed in a portion of the pumping plate 116 closer to the side wall of the processing chamber. In such a manner, the pumping plate 116 can be used to reduce the flow of hydrogen radicals away from the workpiece and out of the processing chamber 110. As such, the pumping plate 116 increases radical concentration at the surface of the workpiece 114. Further, the pumping plate 116 can be configured to reduce radical dissemination (e.g., hydrogen radical dissemination) in the processing chamber 110. A heater 113 can be disposed in the workpiece support 112 and is configured to heat the workpiece 114.

The example plasma processing apparatus 100 of FIG. 1 can be operable to generate a first plasma (e.g., a remote plasma) in the plasma chamber 120 and a second plasma (e.g., a direct plasma) in the processing chamber 110. For instance, the plasma processing appratus 100 can include a bias source having a bias electrode 510 in the workpiece support 112. The bias electrode 510 can be coupled to an RF power generator 514 via a suitable matching network 512. When the bias electrode 510 is energized with RF energy, a second plasma can be generated from a mixture in the processing chamber 110 for direct exposure to the workpiece 114. The processing chamber 110 can include a gas exhaust port 516 for evacuating a gas from the processing chamber 110. The radicals or species used in the radical treatment process according to example aspects of the present disclosure can be generated using the first plasma and/or the second plasma.

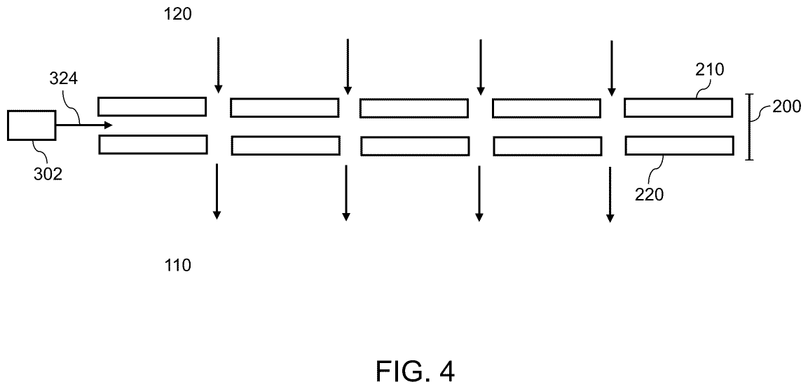

FIG. 4 illustrates an example post plasma gas injection at a separation grid according to example embodiments of the disclosure. FIG. 4 will be discussed with reference to the plasma processing apparatus 100 of FIG. 1 by way of example.

According to example aspects of the present disclosure, the plasma processing apparatus 100 can include one or more gas ports 302 configured to inject a gas into the neutral species flowing through the separation grid 300. For instance, a gas port 302 can be operable to inject a gas (e.g., a cooling gas) between grid plates in a multi-plate separation grid. In this way, the separation grid can provide post plasma gas injection into the neutral species. The post plasma gas injection can provide a number of technical effects and benefits. For example, the gas can be injected, for example, to control uniformity characteristics of a process. For example, a neutral gas (e.g., inert gas) can be injected to control uniformity, such as uniformity in a radial direction with respect to the workpiece. Cooling gas can be injected to control the energy of radicals passing through the separation grid.

The separation grid 300 can be a multi-plate separation grid (e.g., a dual-plate grid (shown in FIG. 1, a three-plate grid, a four-plate grid, etc.). As shown in FIG. 4, the plasma processing apparatus 100 can include a gas port 302 configured to inject a gas 324 between grid plate 210 and grid plate 220, such as in the channel formed between grid plate 210 and grid plate 220. More particularly, the mixture of ions and neutral species generated in the plasma can be exposed to grid plate 210. The gas port 302 can inject a gas 324 or other substance into neutral species flowing through the grid plate 210. Neutral species passing through grid plate 320 can be exposed to a workpiece. In some embodiments, the gas port 302 can inject a gas 324 directly into the processing chamber 110 at a location below the separation grid 300 and above the surface of the workpiece 114.

The gas 324 or other substance from the gas port 302 can be at a higher or lower temperature than the radicals coming from the plasma chamber 120 or can be the same temperature as the radicals from the plasma chamber 120. The gas can be used to adjust or correct uniformity, such as radical uniformity, within the plasma processing apparatus 100, by controlling the energy of the radicals passing through the separation grid 200. The non-process gas may include a dilution gas, such as nitrogen (N₂) and/or an inert gas, such as helium (He), argon (Ar) or other inert gas. In some embodiments, the gas 324 can be an inert gas, such as helium, nitrogen, and/or argon. In some aspects, hydrogen radicals can be generated by injecting a hydrogen-containing gas through one or more of the gas ports 302 at or below the separation grid 300 into the filtered plasma species in order to generate additional hydrogen radicals.

Aspects of the present disclosure are also directed to a hydrogen radical treatment process that can be utilized during or after a deposition or etch process in order to close one or more seams present in a metal layer disposed on the workpiece. For instance, metal deposition processes (e.g., CVD) can be utilized to dispose a metal layer on one or more of the surfaces of the workpiece. Depending on the metal layer deposition and the method of deposition, seams or cracks can reside in the metal layer after deposition, which can detrimentally affect the performance of the workpiece.

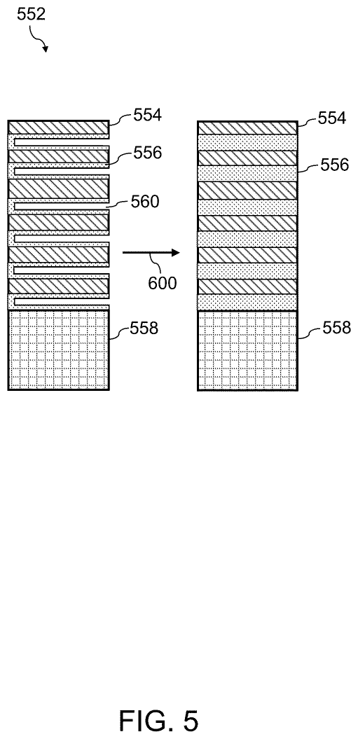

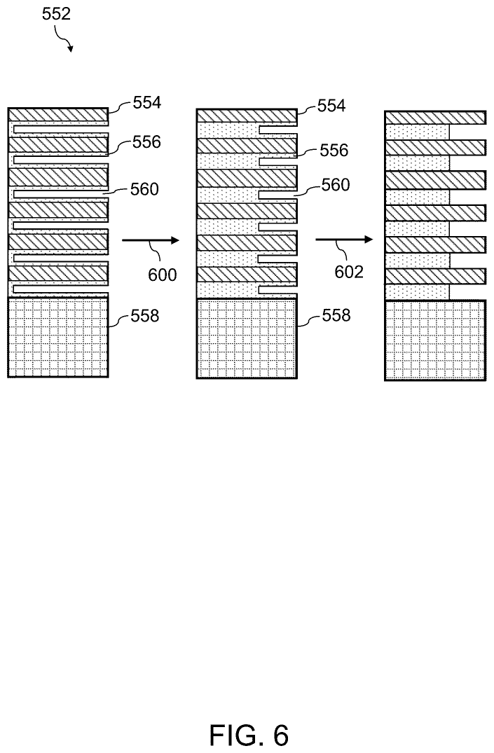

FIG. 5 depicts an example of an imperfect vertical loading shape for a workpiece having a high aspect ratio structure 552. The high aspect ratio structure 552 includes a plurality of oxide layers 554 (e.g., silicon oxide), and a plurality of metal layers 556 disposed on a substrate 558, such as a silicon substrate. The metals layers can include a metal material such as cobalt, copper, tungsten, tantalum, molybdenum, titanium nitride, ruthenium, and combinations thereof. The high aspect ratio structure 552 can include a plurality of oxide layers and a plurality of metal layers arranged in an alternating fashion. For example, as shown in FIG. 6, the high aspect ratio structure 552 may contain a layer of silicon oxide having a layer of metal on top of the silicon oxide in a vertical fashion. This vertical alternating arrangement between the silicon oxide layers 554 and metal layer 556 may be repeated. To deposit the metal layers 556 a metal deposition process can be utilized. During a metal deposition process, metal material can be deposited on each side of the silicon oxide layers 554 resulting in one or more cracks 560 in the deposited metal layers 556. Subsequent etching of the metal layers 556 can cause the crack to widen, which can impair functionality of the workpiece. Accordingly, at 600 a hydrogen radical treatment process can be performed in order to remove any seams or cracks that are present in metal layer 556. For instance, the hydrogen radical process can improve metal flow or grain growth in order to seal any seams or cracks that are present in metal layer 556.

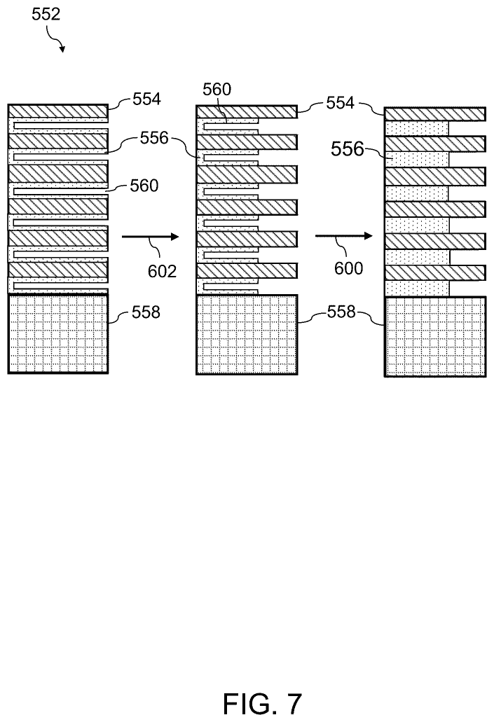

FIG. 6 depicts a depicts an example of an imperfect vertical loading shape for a workpiece 550 having a high aspect ratio structure 552 that is exposed at 600 to a hydrogen radical treatment process and at 602 to an etch process. For instance, as described above with reference to FIG. 5, a metal layer 556 can be deposited in between one or more of the oxide layers 554. During deposition a crack 560 or seam can be formed in between the metal layers as they are deposition on each side of the oxide layer 554. As shown, a hydrogen radical treatment process 600 can be performed in order to eliminate and fill the crack 560. As shown, the hydrogen radical treatment process 600 can be utilized to remove at least a portion of the crack 560. For instance, at least about 20%, such as at least about 30%, such as at least about 40%, such as at least about 50%, such as least about 60%, such as at least about 70%, such as at least about 80%, such as at least about 90%, such as at least about 100% of the crack 560 can be filled or eliminated via the hydrogen radical treatment process 600. At an etch process 602 can then be performed to laterally etch the metal layers 556 with respect to the oxide layers 554. The etch process 602 can be performed on the high aspect ratio structure 552 to etch a first portion of the metal layers 554 from the high aspect ratio structure 552. In certain instances, the plurality of metal layers 554 are removed laterally from the high aspect ratio structure 552. With reference to FIG. 6, laterally is shown as removal in the horizontal plane of the figure. As shown, etching the metal layers 556 from the high aspect ratio structure 552 can include etching the metal layers 556 at an etch rate greater than an etch rate of the plurality of oxide layers 554. As shown in FIG. 7, in embodiments, the etch process 602 can take place after the metal deposition process but prior to the hydrogen radical treatment process 600.

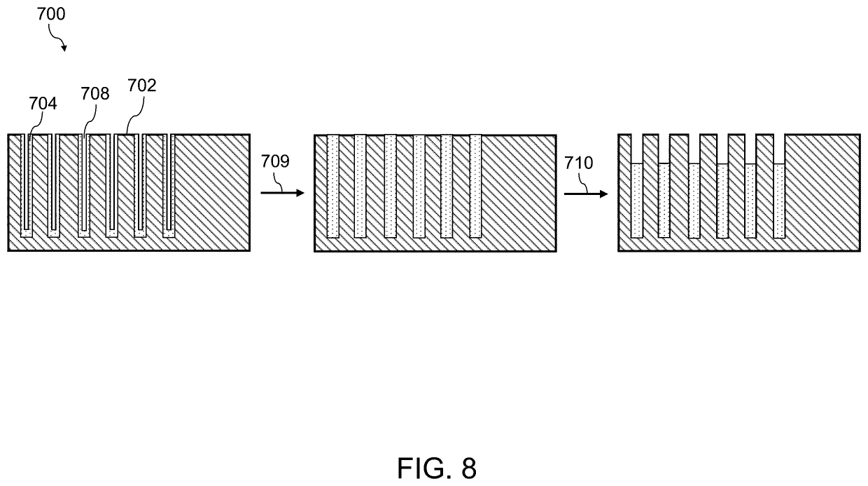

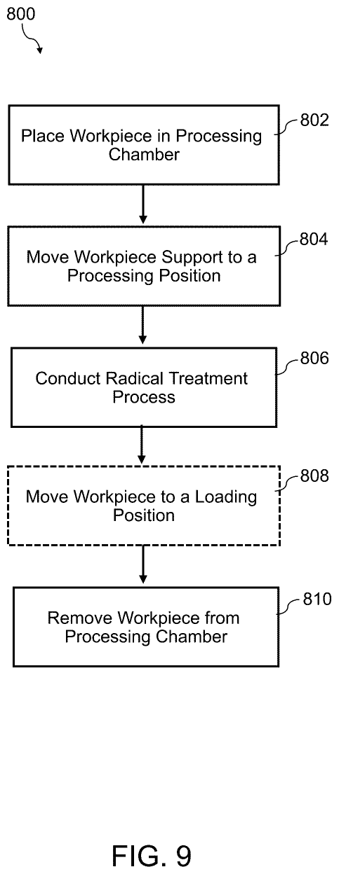

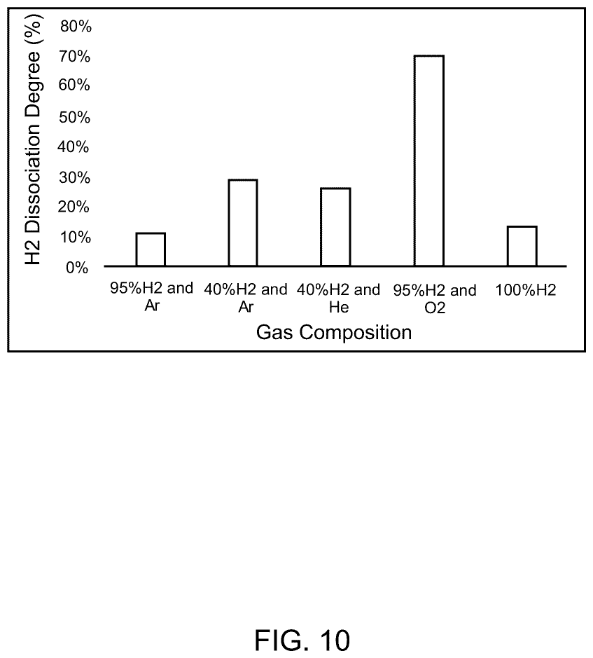

FIG. 8 illustrates a metal etching process including a hydrogen treatment process for etching metal layers in a vertical manner with respect to a high aspect ratio structure. For instance, a high aspect ratio structure 700 is shown. The high aspect ratio structure 700 includes a plurality of oxide layers 702 (e.g., silicon oxide) and a plurality of metal layers 704. The oxide layers 702 and metal layers 704 can be disposed on a substrate, such as a silicon substrate. The high aspect ratio structure 706 can include a plurality of oxide layers and a plurality of metal layers arranged in an alternating fashion. For example, as shown in FIG. 8, the high aspect ratio structure 700 may contain alternating layers of silicon oxide and metal layers arranged in a horizontal fashion. The metal layers 704 can be placed within a critical dimension CD between the horizontally arranged layers of silicon oxide. In such an embodiment, it is desirous to etch metal layer from the high aspect ratio structure 700 in a vertical or top-down matter. The etch process 710 is thus configured to remove metal layers from the metal layers 704 in a vertical manner. To deposit the metal layers 704 a metal deposition process can be utilized. During a metal deposition process, metal material can be deposited within the critical dimension and on each side of the oxide layers 702 resulting in one or more cracks 708 in the deposited metal layer 704. Exposure of the high aspect ratio structure 700 to an etch process 710 can cause the crack 1708 to widen, which can impair functionality of the workpiece.

Accordingly, as shown in FIG. 8, at 720 a hydrogen radical treatment process 709 can be performed in order to remove at least a portion or all of the crack 708 from the metal layer 704. For instance, the hydrogen radical process can improve metal flow or grain growth to seal any seams or cracks that are present in the metal layer 704. The high aspect ratio structure 700 can then be exposed to an etch process 710 in order to remove all or a portion from the metal layers 704.

FIG. 9 depicts a flow diagram of one example method (800) according to example aspects of the present disclosure. The method (800) will be discussed with reference to the plasma processing apparatus 100 of FIG. 1 by way of example. The method (800) can be implemented in any suitable plasma processing apparatus. FIG. 9 depicts steps performed in a particular order for purposes of illustration and discussion. Those of ordinary skill in the art, using the disclosures provided herein, will understand that various steps of any of the methods described herein can be omitted, expanded, performed simultaneously, rearranged, and/or modified in various ways without deviating from the scope of the present disclosure. In addition, various steps (not illustrated) can be performed without deviating from the scope of the present disclosure. Further, while FIG. 1 is utilized for the purpose of discussion, those of ordinary skill in the art, using the disclosures provided herein, will understand that any plasma source (e.g., inductively coupled plasma source, capacitively coupled plasma source, etc.) can be used without deviating from the scope of the present disclosure.

At (802), the method can include placing a workpiece in a processing chamber of a plasma processing apparatus 100. The processing chamber 110 can be separated from a plasma chamber 120 (e.g., separated by a separation grid assembly). For instance, the method can include placing a workpiece 114 onto workpiece support 112 in the processing chamber 110 of FIG. 1. The workpiece may include a metal layer, an oxide layer, or both. In certain embodiments, the workpiece includes a metal layer that comprises copper, tungsten, cobalt, ruthenium, or combinations thereof. In embodiments, the oxide layer includes a silicon oxide layer.

At (804), the method can include moving the workpiece support 112 to a procesing position. For instance, the workpiece support 112 and/or workpiece 114 can be moved towards the plasma chamber 120 and/or the separation grid assembly 200 in order to close a distance between the focus ring 111 and the workpiece support 112. Notably, moving the workpiece support 112 to a second vertical position (e.g., a processing position) reduces the distance that radicals are required to travel to contact the surface of the workpiece. Further, the focus ring 111 provides a sidewall that prevents diffusion of the radicals in the processing chamber 110. Accordingly, a greater number of radicals (e.g., hydrogen radicals) are able to come into contact with the workpiece 114.

At (806), the method can include exposing the workpiece to a hydrogen radical treatment process. Exposure of the workpiece to the hydrogen radicals can heat or chemically modify the metal layer such that any cracks or seams within the metal layer can be closed or eliminated from the workpiece. For instance, exposure of the workpiece to the hydrogen radical treatment process can facilitate metal annealing, grain growth, or redistributed grain flow of the metal layer such that any seams or cracks present in the metal layer are closed. The hydrogen radical treatment process includes exposing the workpiece to hydrogen radicals. The hydrogen radical treatment process can include generating one or more species from a process gas in the plasma chamber; filtering the one or more species to create a filtered mixture containing one or more radicals, and exposing the workpiece to the hydrogen radicals to seal or close any cracks or seams present in the metal layer.

The process gas used for the hydrogen radical treatment process may include a hydrogen-containing gas (H₂), an oxygen-containing gas (O₂), or combinations thereof. For example, in certain embodiments, the gas delivery system 150 may be configured to deliver process gas to the plasma chamber 120, for instance, via gas distribution channel 151 or other distribution system (e.g., showerhead). The gas delivery system can include a plurality of feed gas lines 159. The feed gas lines 159 can be controlled using valves and/or mass flow controllers to deliver a desired amount of gases into the plasma chamber as process gas. As shown in FIG. 1, the gas delivery system 150 can include feed gas line(s) for delivery of a hydrogen-containing gas (e.g., H₂). The gas delivery system 150 can include feed gas line(s) for delivery of an oxygen-containing gas (e.g., O₂). The gas delivery system 150 can include feed gas line(s) for delivery of a dilution gas (e.g., N₂, Ar, He, or other inert gas).

In some embodiments, the process gas may contain from about 10% by volume to about 99% by volume of a hydrogen-containing gas (H₂). In embodiments, the process gas may contain from about 85% to about 99% by volume of a hydrogen-containing gas (H₂). The hydrogen-containing gas can include H₂, D₂, NH₃, or CH₄. In certain embodiments, the process gas includes a hydrogen-containing gas (H₂) mixed with at least one other gas, such as an inert gas (e.g., Ar, He, Ne) or an oxygen-containing gas (e.g., O₂). In such embodiments, hydrogen-containing gas is present in an amount of from about 95 vol. % to about 40 vol. % and the at least one other gas in present in amounts ranging from about 5 vol. % to about 60 vol. %. While not being bound by any particular theory, it is believed that the inclusion of a certain amount of non-hydrogen gas in the process gas, can enhance hydrogen dissociation in the plasma.

In other embodiments, the process gas may contain from about 1% by volume to about 50% by volume of an oxygen-containing gas (O₂). In embodiments, the process gas may contain from about 5% to about 10% by volume of an oxygen-containing gas. The oxygen-containing gas can include O₂, H₂O, NO₂, O₃, CO₂, CO, NO, or mixtures thereof.

In certain embodiments, the hydrogen radical treatment process includes generating one or more species from a process gas in the plasma chamber. To generate one or more species, the induction coil 130 can be energized with RF power from the RF power generator 134, to generate a plasma from the process gas in the plasma chamber. The plasma generated can include one or more species including hydrogen radicals, oxygen radicals, and combinations thereof.

The hydrogen radical treatment process can include filtering the one or more species to create a filtered mixture. To create a filtered mixture, in some embodiments, the one or more species can be filtered via a separation grid 200 that separates the plasma chamber 120 from the processing chamber. The separation grid 200 can be used to perform ion filtering from a mixture generated by plasma in the plasma chamber 120 to generate a filtered mixture. The filtered mixture can include hydrogen radicals, oxygen radicals, and combinations thereof.

In some embodiments, the separation grid 200 can be a multi-plate separation grid. The multi-plate separation grid can have multiple separation grid plates in parallel. The arrangement and alignment of holes in the grid plate can be selected to provide a desired efficiency for ion filtering, such as greater than or equal to about 95%. For instance, in some embodiments, the separation grid is configured to provide ion filtering of at least 90% meaning that at least 90% of the ions are filtered from the filtered mixture. In certain embodiments, the separation grid is configured to provide ion filtering of at least 95%, such as at least 99%, meaning that at least 95% and up to 99% of the ions are filtered from the filtered mixture.

In some embodiments, the workpiece is at a process pressure when exposed to the filtered mixture. For example, in some embodiments, the process pressure may be from about 400 mT to about 1000 mT. Without being bound by any particular theory, maintaining or utilizing the disclosed process pressures herein may lead to increased selectivity for heating the metal layer with respect to other material layers, such as dielectric material layers, on the workpiece. For example, utilization of a process pressure greater than 1100 mT can negatively affect the annealing temperature of the metal layer, which is not desirable.

In certain embodiments, the workpiece is at a processing temperature when exposed to the filtered mixture. For instance, the processing temperature can be from about 400° C. to about 1,200° C., such as from about 500° C. to about 1,100° C., such as from about 600° C. to about 1,000° C., such as from about 700° C. to about 900° C. In embodiments, exposure of the metal layer to the hydrogen radicals can increase the temperature of the workpiece, including the metal layers disposed thereon. Advantageously, the provided methods allow for metal layers on the workpiece to reach very high temperatures, sufficient for closing seams or cracks in the metal layer without substantially raising the temperature of other material layers on the workpiece.

In certain embodiments, the workpiece may be exposed to the filtered mixture for a certain process time. In some embodiments, the process time may be from about 30 sec to about 1800 sec., such as from about 30 sec. to about 1200 sec.

Optionally, at (808) the method can include conducting an etch process on the workpiece. The etch process can include generating one or more species from a process gas in the plasma chamber, filtering the one or more species to create a filtered mixture, and exposing the workpiece to the filtered mixture. Exposure of the workpiece to the filtered mixture etches metal material or a metal layer from the workpiece 114. The process gas used for the etch process can include a fluorine-containing gas, a hydrogen-containing gas, an oxygen-containing gas, or an inert gas (e.g., Ar, Ne, N₂). The gas delivery system 150 may be configured to deliver the process gas to the plasma chamber 120, for instance, via gas distribution channel 151 or other distribution system (e.g., showerhead). The gas delivery system can include a plurality of feed gas lines 159. The feed gas lines 159 can be controlled using valves and/or mass flow controllers to deliver a desired amount of gases into the plasma chamber as process gas. The gas delivery system 150 can include feed gas line(s) for delivery of a fluorine-containing gas (e.g., NF₃). The gas delivery system 150 can include feed gas line(s) for delivery of an oxygen-containing gas (e.g., O₂). The gas delivery system can include feed gas line(s) for delivery of a hydrogen-containing gas (e.g., H₂). The gas delivery system 150 can include feed gas line(s) for delivery of a dilution gas (e.g., N₂, Ar, He, or other inert gas).

In certain embodiments, the etch process includes generating one or more species from a process gas in the plasma chamber. To generate the one or more species, the induction coil 130 can be energized with RF power from the RF power generator 134, to generate a plasma from the process gas in the plasma chamber. The plasma generated can include one or more species including fluorine radicals (e.g., etchant radicals), hydrogen radicals, oxygen radicals, methane radicals, and combinations thereof.

The etch process can include filtering the one or more species to create a filtered mixture. To create a filtered mixture, in some embodiments, the one or more species can be filtered via a separation grid 200 that separates the plasma chamber 120 from the processing chamber. The separation grid 200 can be used to perform ion filtering from a mixture generated by plasma in the plasma chamber 120 to generate a filtered mixture.

The filtered mixture can be exposed to the workpiece 114 in the processing chamber. Exposure of the workpiece 114 to the filtered mixture can etch metal materials or metal layers from a rate that is faster than etching of silicon oxide or silicon nitride layers present on the workpiece.

At (808), the method can include moving the workpiece support and/or the workpiece to a loading position. For instance, the workpiece support 112 can be moved away from the separation grid assembly 220 and/or plasma chamber 120 in order to increase the distance between the focus ring 111 and the workpiece support 112. Moving the workpiece support to a first vertical position (e.g., non-processing position) increases the distance between the focus ring 111 and the workpiece 114 such that the workpiece 114 can be easily removed from the processing chamber 120.

At (810), the method can include removing the workpiece from the processing chamber. For instance, the workpiece 114 can be removed from workpiece support 112 in the processing chamber 110. The plasma processing apparatus can then be conditioned for future processing of additional workpieces.

Example process parameters for the hydrogen radical treatment process for closing one or more seams in a metal layer will now be set forth.

### Example 7

Process Gas: H2
Dilution Gas: O2, He
Process Pressure: 100 mT to 8000 mT
Inductively Coupled Plasma Source Power: 1000W to 5000W
Workpiece Temperature: 250C to 900C
Process Period (time): 60 s to 1200 s
Gas Flow Rates for Process Gas:
O₂: 0 sccm to 2000 sccm
H₂: 1000 sccm to 20000 sccm
He: 500 sccm to 10000 sccm
   FIG. 10 illustrates the percent of hydrogen dissociation based on the gas percentage. All percentages are volume percent. As shown, inclusion of an additional gas in the processing gas can facilitate hydrogen dissociation. For instance, hydrogen dissociation was increased when the process gas mixture included 95 vol. % hydrogen and 5 vol. % oxygen. Hydrogen dissociation also improved in mixtures containing 95 vol. % hydrogen and 5 vol. % argon, 40 vol % hydrogen and 60 vol. % argon, and 40 vol. % hydrogen and 60 vol. % helium. Accordingly, inclusion of about 5 vol. % up to 60 vol. % of another gas can increase hydrogen dissociation.

Embodiments of the present disclosure are also provided in the following clauses.

A method for conducting a thermal treatment process on a workpiece in a processing apparatus, the processing apparatus comprising a plasma chamber and a processing chamber, and the processing chamber having a workpiece support operable to support a workpiece, the method comprising: placing the workpiece on the workpiece support in the processing chamber; moving the workpiece support towards the plasma chamber to close a distance between a focus ring and the workpiece support; and conducting a radical treatment process on the workpiece, comprising exposing the workpiece to hydrogen radicals in the processing chamber, the hydrogen radicals configured to close one or more seams in a metal layer on the workpiece.

The method of any preceding clause, wherein the hydrogen radicals are generated in the plasma chamber.

The method of any preceding clause, wherein the hydrogen radicals are generated by inducing a plasma in a process gas mixture using an inductively coupled plasma source, and the process gas mixture comprising from about 10% to about 100% by volume of a hydrogen-containing gas.

The method of any preceding clause, wherein the process gas mixture comprises from about 10% to about 50% by volume of an oxygen containing gas.

The method of any preceding clause, wherein the process gas mixture comprises helium, nitrogen, or argon.

The method of any preceding clause, wherein the hydrogen-containing gas comprises H₂, D₂, NH₃, or CH₄.

The method of any preceding clause, wherein the oxygen containing gas comprises O₂, H₂O, NO₂, O₃, CO₂, CO, or NO.

The method of any preceding clause, wherein exposing the workpiece to hydrogen radicals in the processing chamber comprises: generating one or more species from a process gas using a plasma in the plasma chamber, wherein the process gas comprises a hydrogen-containing gas and an oxygen-containing gas; filtering the one or more species to create a filtered mixture, wherein the filtered mixture comprises hydrogen radicals and oxygen radicals; and exposing the workpiece to the hydrogen radicals and oxygen radicals.

The method of any preceding clause, wherein the workpiece comprises a plurality of alternating silicon oxide layers, wherein a metal layer is deposited between each silicon oxide layer.

The method of any preceding clause, wherein one or more seams are formed in the metal layer deposited between one or more silicon oxide layers.

The method of any preceding clause, wherein the metal layer comprises cobalt, copper, tungsten, tantalum, ruthenium, molybdenum, or titanium nitride.

The method of any preceding clause, comprising conducting an etch process on the metal layer before or after the radical treatment process.

The method of any preceding clause, wherein the etch process comprises exposing the workpiece to one or more etchant radicals generated in a remote plasma.

The method of any preceding clause, wherein the etchant radicals are configured to etch the metal layer at an etch rate that is faster than an etch rate of a silicon oxide material.

The method of any preceding clause, wherein the plasma chamber and the processing chamber are separated by a plurality of separation grids operable to filter ions generated in the plasma chamber.

The method of any preceding clause, wherein the workpiece is at a temperature of from about 250° C. to about 900° C. during the radical treatment process.

The method of any preceding clause, wherein a process pressure is from about 100 mT to 8000 mT during the radical treatment process.

The method of any preceding clause, wherein the radical treatment process causes grain growth of the metal layer such that the one or more seams can be closed.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A processing apparatus for processing a workpiece comprising:
a processing chamber;
a plasma chamber separated from the processing chamber;
a gas delivery system configured to deliver one or more process gases to the plasma chamber;
a plasma source configured to generate a plurality of radicals in a plasma from the one or more process gases in the plasma chamber;
a workpiece support disposed within the processing chamber, the workpiece support configured to support a workpiece; and
a focus ring configured to direct the plurality of radicals towards the workpiece.

2. The processing apparatus of claim 1, wherein the workpiece support is configured to adjust a distance between the workpiece support and the focus ring.

3. The processing apparatus of claim 2, wherein the distance between the workpiece support and the focus ring during processing of the workpiece is from about 1 mm to about 50 mm.

4. The processing apparatus of claim 1, wherein the processing chamber comprises one or more walls having one or more cooling channels disposed therein.

5. The processing apparatus of claim 1, comprising a cooling mechanism configured to cool one or more walls of the plasma chamber.

6. The processing apparatus of claim 1, comprising an induction coil disposed around the plasma chamber, the induction coil configured to generate an inductively coupled plasma.

7. The processing apparatus of claim 6, comprising one or more magnetic coils disposed around the plasma chamber.

8. The processing apparatus of claim 7, wherein the one or more magnetic coils comprise a first magnetic coil disposed above the induction coil and a second magnetic coil disposed below the induction coil.

9. The processing apparatus of claim 7, wherein the one or more magnetic coils are configured to confine the plasma generated in the plasma chamber.

10. The processing apparatus of claim 1, comprising a pumping plate disposed under the workpiece support, the pumping plate configured to reduce hydrogen radical dissemination in the processing chamber.

11. The processing apparatus of claim 10, wherein the pumping plate comprises one or more apertures, wherein a greater amount of apertures are present at a portion of the pumping plate closest to the workpiece support.

12. The processing apparatus of claim 1, wherein the plasma chamber and the processing chamber are separated via one or more separation grids.

13. The processing apparatus of claim 12, wherein the focus ring is disposed in the processing chamber on a first side of the one or more separation grids.

14. The processing apparatus of claim 12, wherein the one or more separation grids comprise one or more cooling channels disposed therein.

15. The processing apparatus of claim 1, wherein the focus ring is formed from a quartz material.

16. The processing apparatus of claim 1, comprising a heater in the workpiece support configured to heat the workpiece.

17. The processing apparatus of claim 1, wherein the plurality of radicals comprise hydrogen radicals.

18. The processing apparatus of claim 17, wherein the hydrogen radicals are generated by inducing a plasma in the one or more process gases using an inductively coupled plasma source, and the one or more process gases comprise from about 10% to about 100% by volume of a hydrogen-containing gas.

19. The processing apparatus of claim 18, wherein the one or more process gases comprise helium, nitrogen, or argon.
